(19) United States
(12) Patent Application Publication
(10) Pub. No.: US 2021/0323287 A1
(43) Pub. Date: Oct. 21, 2021

(54) WINDOW AND DISPLAY DEVICE INCLUDING THE SAME

(71) Applicant: Samsung Display Co., Ltd., Yongin-Si (KR)

(72) Inventors: YOUNGOK PARK, Seoul (KR); HYUK-HWAN KIM, Suwon-si (KR)

(21) Appl. No.: 17/197,447

(22) Filed: Mar. 10, 2021

(30) Foreign Application Priority Data
Apr. 21, 2020 (KR) 10-2020-0047887

(51) Int. Cl. B32B 27/08

(52) U.S. Cl. CPC B32B 27/08; B32B 2262/062; B32B 2457/20

(57) ABSTRACT

A display device includes a display panel having a light emitting element. A nano-cellulose sheet is disposed on the display panel. The nano-cellulose sheet is configured to transmit light generated from the light emitting element. The nano-cellulose sheet includes a plurality of layers that are sequentially laminated Each of the plurality of layers includes a pattern comprising a nano-cellulose fiber arranged in a hexagonal shape.

### CROSS-REFERENCE TO RELATED APPLICATIONS

This application claims priority wider 35 U.S.C. § 119 to Korean Patent Application No. 10-2020-0047887, tiled on Apr. 21, 2020 in the Korean Intellectual Property Office, the disclosure of which is incorporated by reference in its entirety herein.

### 1. TECHNICAL FIELD

The present inventive concepts relate to a window and a display device, and more particularly, to a window having increased reliability.

### 2. DISCUSSION OF RELATED ART

A display device includes a display panel that generates an image for viewing by a user and a window for protecting the display panel.

Display devices having various shapes have recently been developed, such as a display device including a curved surface, a rollable display device, or a foldable display device. Research has been performed to increase the flexibility and light-transmitting property of a window for the display device.

For example, it may he advantageous for a window of a display device having a relatively small thickness to have an increased flexibility and light-transmitting property. The window may be made of various materials such as glass, a synthetic resin, and a natural polymer resin.

### SUMMARY

The present inventive concepts provide a window having excellent light transmitting property and flexibility while having a slim thickness.

The present inventive concepts also provide a display device including a window having improved property.

According to an exemplary embodiment of the present inventive concepts, a display device includes a display panel having a light emitting element. A nano-cellulose sheet is disposed on the display panel. The nano-cellulose sheet is configured to transmit light generated from the light emitting element. The nano-cellulose sheet includes a plurality of layers that are sequentially laminated. Each of the plurality of layers includes a pattern comprising a nano-cellulose fiber arranged in a hexagonal shape.

In an exemplary embodiment, the pattern may extend in a first direction and a second direction crossing the first direction, and the first layer to the third layer may be laminated in a third direction crossing each of the first direction and the second direction.

In an exemplary embodiment, the nano-cellulose sheet may have a surface modulus less than a cross-sectional modulus thereof, the surface modulus may be a modulus of a surface parallel to a surface defined by the first direction and the second direction, and the cross-sectional modulus may be a modulus of a surface crossing the surface defined by the first direction and the second direction.

In an exemplary embodiment, in a first pattern contained in the first layer, a second pattern contained in the second layer, and a third pattern contained in the third layer, the first to third patterns may have the same shape as each other, and the first to third layers may be laminated so that the first pattern and the third pattern are aligned on a plane, and the second pattern is misaligned with each of the first pattern and the third pattern.

In an exemplary embodiment, in a first nano-cellulose fiber contained in the first pattern, a second nano-cellulose fiber contained in the second pattern, and a third nano-cellulose fiber contained in the third pattern, the first nano-cellulose fiber and the third nano-cellulose fiber may overlap each other on a plane, and the second nano-cellulose fiber may not overlap the first nano-cellulose fiber and the third nano-cellulose fiber.

In an exemplary embodiment, the nano-cellulose sheet may have a thickness equal to or greater than about 0.35 mm and equal to or less than about 0.6 mm.

In an exemplary embodiment, a hexagonal shape of the pattern to have a diameter equal to or greater than about 10 μm and equal to or less than about 50 μm.

In an exemplary embodiment, a hexagonal opening may be defined in the pattern.

In an exemplary embodiment, the pattern may be provided in a spray coating method.

In an exemplary embodiment, an ink layer having a predetermined color may be further provided on a bottom surface of the nano-cellulose sheet.

In an exemplary embodiment, at least one of the first to third layers may have a thickness equal to or greater than about 5 μm and equal to or less than about 7 μm.

According to an exemplary embodiment of the present inventive concepts, a window includes a nano-cellulose sheet having a light transmitting property. The nano-cellulose sheet includes a base layer and a pattern. The nano-cellulose sheet includes a plurality of layers that are sequentially laminated. The pattern comprises nano-cellulose fibers arranged in a hexagonal shape.

In an exemplary embodiment, the pattern may extend in a first direction and a second direction crossing the first direction, and the first layer to the third layer may be laminated in a third direction crossing each of the first direction and the second direction.

In an exemplary embodiment, the nano-cellulose sheet may have a surface modulus less than a cross-sectional modulus thereof, the surface modulus may be a modulus of a surface parallel to a surface defined by the first direction and the second direction, and the cross-sectional modulus may be a modulus of a surface crossing the surface defined by the first direction and the second direction.

In an exemplary embodiment, in a first nano-cellulose fiber contained in the pattern of the first layer, a second nano-cellulose fiber contained in the pattern of the second layer, and a third nano-cellulose fiber contained in the pattern of the third layer, the first nano-cellulose fiber and the third nano-cellulose fiber may overlap each other on a plane, and the second nano-cellulose fiber may not overlap the first nano-cellulose fiber and the third nano-cellulose fiber.

In an exemplary embodiment, the nano-cellulose sheet may have a thickness equal to or greater than about 0.35 mm and equal to or less than about 0.6 mm.

In an exemplary embodiment, a hexagonal shape of the pattern may leave a diameter equal to or greater than about 10 μm and equal to or less than about 50 μm.

In an exemplary embodiment, a hexagonal opening may be defined in the pattern.

In an exemplary embodiment, the pattern may be provided in a spray coating method.

In an exemplary embodiment, at least one of the first to third layers may have a thickness equal to or greater than about 5 μm and equal to or less than about 7 μm.

According to an exemplary embodiment of the present inventive concepts, a display device includes a display panel including a light emitting element. A window is disposed on the display panel. The window includes a nano-cellulose sheet that is configured to transmit light generated from the light emitting element. The nano-cellulose sheet includes a plurality of layers that are sequentially laminated. Each of the plurality of layers includes a pattern comprised of at least one nano-cellulose fiber arranged in a shape that forms a plurality of openings.

### BRIEF DESCRIPTION OF THE DRAWINGS

The accompanying drawings are included to provide a further understanding of the present inventive concepts, and are incorporated in and constitute a part of this specification. The drawings illustrate exemplary embodiments of the present inventive concepts and, together with the description, serve to explain principles of the present inventive concepts in the drawings:

FIG. 1 is a perspective view illustrating a display device according to an exemplary embodiment of the present inventive concepts;

FIG. 2 is a cross-sectional view taken along line I-I′ of FIG. 1 according to an exemplary embodiment of the present inventive concepts;

FIG. 3 is a perspective view illustrating a nano-cellulose sheet according to an exemplary embodiment of the present inventive concepts;

FIG. 4 is an exploded perspective view illustrating the nano-cellulose sheet according to an exemplary embodiment of the present inventive concepts;

FIG. 5 is a cross-sectional view taken along line II-II′ of FIG. 3 according to an exemplary embodiment of the present inventive concepts; and

FIG. 6 is a perspective view and an enlarged view illustrating a pattern of the nano-cellulose sheet according to exemplary embodiments of the present inventive concepts.

### DETAILED DESCREPTION OF EXEMPLARY EMBODIMENTS

Since the present inventive concepts may have diverse modified embodiments specific exemplary embodiments are illustrated in the drawings and are described in the detailed description of exemplary embodiments. However, the present inventive concepts are not limited to the specific exemplary embodiments and it should be understood that the present inventive concepts cover all the modifications, equivalents, and replacements within the idea and technical scope of the present inventive concepts.

In this specification, it will also be understood that when one component (or region, layer, portion) is referred to as being ‘on’, ‘connected to’, or ‘coupled to’ another component, it can be directly disposed/connected/coupled onto the one component, or an intervening third component may also be present.

In this specification, it will be understood that when a component, layer, a film, a region, a portion, or a plate “directly contacts” another component, layer, film, region, portion or plate, there are no intervening elements therebetween. For example, a feature of being “directly disposed” may represent that two layers or two members that are disposed in direct contact with each other without using an additional intervening member such as an adhesive members disposed therebetween.

Like reference numerals refer to like elements throughout. Also, in the figures, the thickness, ratio, and dimensions of components are exaggerated for clarity of illustration.

The term “and/or” includes any and all combinations of one or more of the associated listed items.

It will be understood that although the terms such as ‘first’ and ‘second’ are used herein to describe various elements, these elements should not be limited by these terms. The terms are only used to distinguish one component from other components. For example, a first element referred to as a first element in one embodiment can be referred to as a second element in another embodiment without departing from the scope of the appended claims. The terms of a singular form may include plural forms unless referred to the contrary.

Also, “under”, “below”, “above”, “upper”, and the like are used for explaining relation association of components illustrated in the drawings. The terms may be a relative concept and described based on directions expressed in the drawings and are not limiting.

Unless otherwise defined, all terms (including technical and scientific terms) used herein have the same meaning as generally understood by those skilled in the art. Terms as defined in a commonly used dictionary should be construed as having the same meaning as in an associated technical context, and unless defined apparently in the description, the terms are not ideally or excessively construed as having formal meaning.

The meaning of “include” or “comprise” specifies a property, a fixed number, a step, an operation, an element, a component or a combination thereof, but does not exclude other properties, fixed numbers, steps, operations, elements, components or combinations thereof.

Hereinafter, a window according to an exemplary embodiment of the present inventive concepts and a display device including the window will be described with reference to the accompanying drawings.

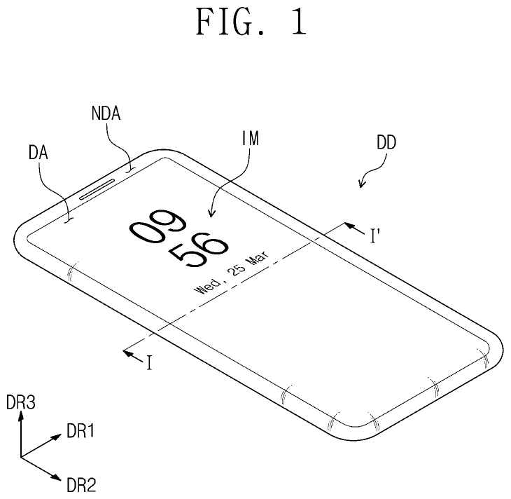

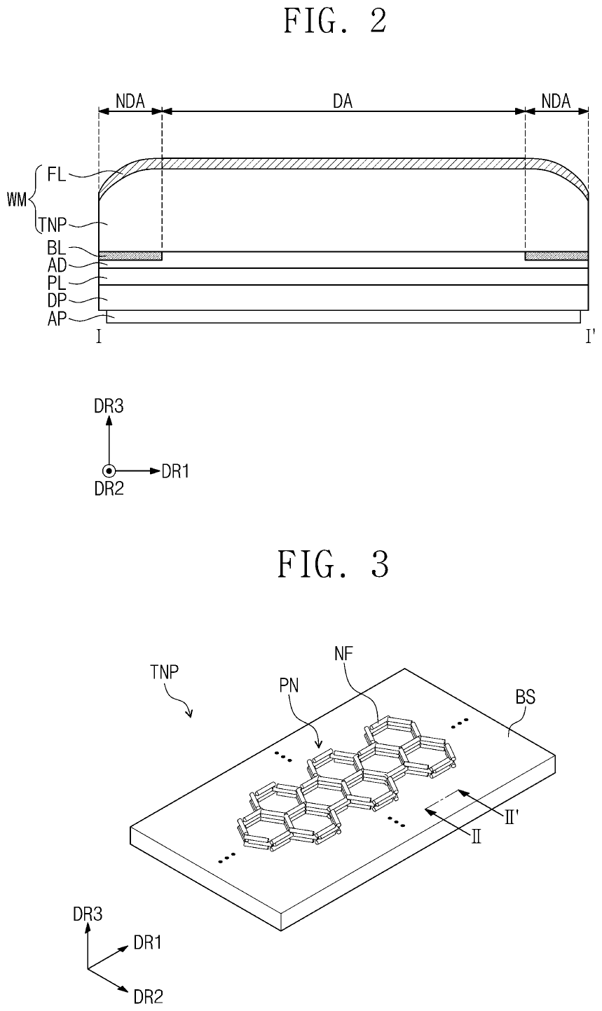

FIG. 1 is a perspective view illustrating a display device DD according to an exemplary embodiment of the present inventive concepts. FIG. 2 is a cross-sectional view taken along line I-I′ of FIG. 1.

Although a smartphone is illustrated as an example of the display device in FIG. 1 exemplary embodiments of the present inventive concepts are not limited thereto. For example, in another exemplary embodiment of the present inventive concepts, the display device DD may be mounted to large-sized electronic devices such as televisions, billboards and monitors and small and medium-sized electronic devices such as tablet computers, navigation units for vehicles, dame consoles, and smart watches. However, exemplary embodiments of the present inventive concepts are not limited thereto.

A display area DA and a non-display area NDA may be defined in the display device DD.

The display area DA on which an image IM is displayed may extend in a plane defined in a first direction DR1 and a second direction DR2. As shown in the exemplary embodiment of FIG. 1, the first direction DR1 and the second direction DR2 may be perpendicular to each other. However, exemplary embodiments of the present inventive concepts are not limited thereto and the first direction DR1 may cross the second direction DR2 at other angles in further exemplary embodiments. In the exemplary embodiment of FIG. 1, the image IM is shown as being a clock and calendar. However, exemplary embodiments of the present inventive concepts are not limited thereto and the image IM may be one or more moving and/or still images of various subject matter.

A normal direction of the display area DA, (e.g., a thickness direction of the display device DD) is indicated by a third direction DR3 which is perpendicular to the first and second directions DR1, DR2. A front surface (e.g a top surface) and a rear surface (e.g., a bottom surface) of the display device DD are spaced apart in the third direction DR3. However, directions indicated by the first to third directions DR1, DR2, and DR3 may be a relative concept and converted with respect to each other.

Although a shape of the display area DA is exemplary illustrated in FIG. 1 as a rectangular shape with rounded corners, exemplary embodiments of the present inventive concepts are not limited thereto. For example, it a other exemplary embodiments, the shape of the display area DA may be variously changed and may be a polygonal shape, a circular shape, an irregular shape, a three-dimensional shape, etc.

The non-display area NDA is an area adjacent to the display area DA and on which the image IM is not displayed. The non-display area NDA may define a bezel area of the display device DD.

The non-display area NDA may surround the display area DA. For example, as shown in the exemplary embodiment of FIG. 1, the non-display area NDA may surround all four sides of the display area DA (e.g., in the first and second directions DR1, DR2). However, exemplary embodiments of the present inventive concepts are not limited thereto. For example, the display area DA and the non-display area NDA may be relatively designed in shape. The non-display area NDA may have at least a portion having a curved shape. Additionally, in some exemplary embodiments, one or more sides of the display area DA may extend to an edge of the display device DD and the non-display area NDA may not surround one or more sides of the display area DA.

FIG. 2 is a cross-sectional view taken along line I-I′ of the display device in FIG. 1 according to an exemplary embodiment of the present inventive concepts. Although a cross-section of the display device DD, which is taken along the first direction DR1, is exemplary illustrated in FIG. 2, in an exemplary embodiment, a cross-section of the display device DD, which is taken along the second direction DR2, may have a substantially same shape.

The display device DD may include an auxiliary panel AP, a display panel DP, an anti-reflection layer PL, an adhesive layer AD, an ink layer BL, and a window WM. In an exemplary embodiment, the display device DD may further include a housing for accommodating the auxiliary panel AP, the display panel DP, the anti-reflection layer PL, the adhesive layer AD, the ink layer BL, and the window WM. In an exemplary embodiment, the housing may include a synthetic resin or a metal material, which has a relatively high degree of rigidity. The housing may be coupled to the window WM to support or accommodate components disposed thereon.

The auxiliary panel AP is disposed below the display panel DP (e.g., in the third direction DR3). The auxiliary panel AP may protect the display panel DP from an impact applied therebelow and may assist the discharge of heat generated from the display panel to the outside.

In an exemplary embodiment, the auxiliary panel AP may include a synthetic resin or a metal material. For example, the metal material may be aluminium (AI). However, exemplary embodiments of the present inventive concepts are not limited thereto.

The display panel DP is a component that generates the image IM provided on the display area DA. The display panel DP may be disposed above the auxiliary panel AP (e.g., the third direction DR3). For example, as shown in the exemplary embodiment of FIG. 2, the display panel DP may be disposed directly on the aux panel AP. The display panel DP may include a plurality of transistors and light emitting elements. The light emitting elements may generate light to provide the image IM on the display area DA. For example, in an exemplary embodiment, each of the light emitting, elements may be an organic light emitting element or a micro-LED. However, exemplary embodiments of the present inventive concepts are not limited thereto.

The anti-reflection layer PL may be disposed above the display panel DP. For example, as shown in the exemplary embodiment of FIG. 2, the arts reflection layer PL may be disposed directly above the display panel. DP. However, exemplary embodiments of the present inventive concepts are not limited thereto. The anti-reflection layer PL may prevent reflected light of light that is incident from the outside of the display device DD from being visible to the user. In an exemplary embodiment, the anti-reflection layer PL may include a polarizing layer that polarizes at least a portion of the light incident from the outside of the display device DD. Alternatively, the anti-reflection layer PL may include a color filter layer.

The adhesive layer AD may be disposed between the anti-reflection layer PL and the window WM (e.g., in the third direction DR3) to couple the anti-reflection layer PL and the window WM to each other. In an exemplary embodiment, the adhesive layer AD may be an optically clear adhesive (OCA). However, exemplary embodiments of the present inventive concepts are not limited thereto. For example, the adhesive layer AD may include any component that has a transparent property and allows light generated from the display panel DP to be transmitted therethrough.

The ink layer BL may be disposed on a bottom surface of the window WM. The ink layer BL may have a predetermined color. For example, in an exemplary embodiment, the predetermined color may be black. However, exemplary embodiments of the present inventive concepts are not limited thereto. The non-display area NDA of the display device DD may be defined by the ink layer BL. For example, in an exemplary embodiment, the ink layer BL may be disposed in the non-display area NDA and may not be disposed in the display area DA.

The window WM may transmit the light generated from the display panel DP and protect the display panel DP from the outside. The window WM according to an exemplary embodiment of the present inventive concepts may include a nano-cellulose sheet TNP and a functional layer FL.

The functional layer FL may be disposed above the nano-cellulose sheet TNP. For example, as shown in the exemplary embodiment of FIG. 2, a lower surface of the functional layer FL may directly contact an upper surface of the nano-cellulose sheet TNP. In an exemplary embodiment, the functional layer FL may include a hard coating material having high hardness for protection of the nano-cellulose sheet TNP from an impact applied from the outside. The functional layer FL may include a hard coating layer. In an exemplary embodiment, the functional layer FL may also include an anti-fingerprint layer that prevents a stain from being generated by a fingerprint when an external input such as a touch of the user is applied to the window WM. However, exemplary embodiments of the present inventive concepts are not limited thereto.

The nano-cellulose sheet TNP may transmit the light generated from the display panel DP.

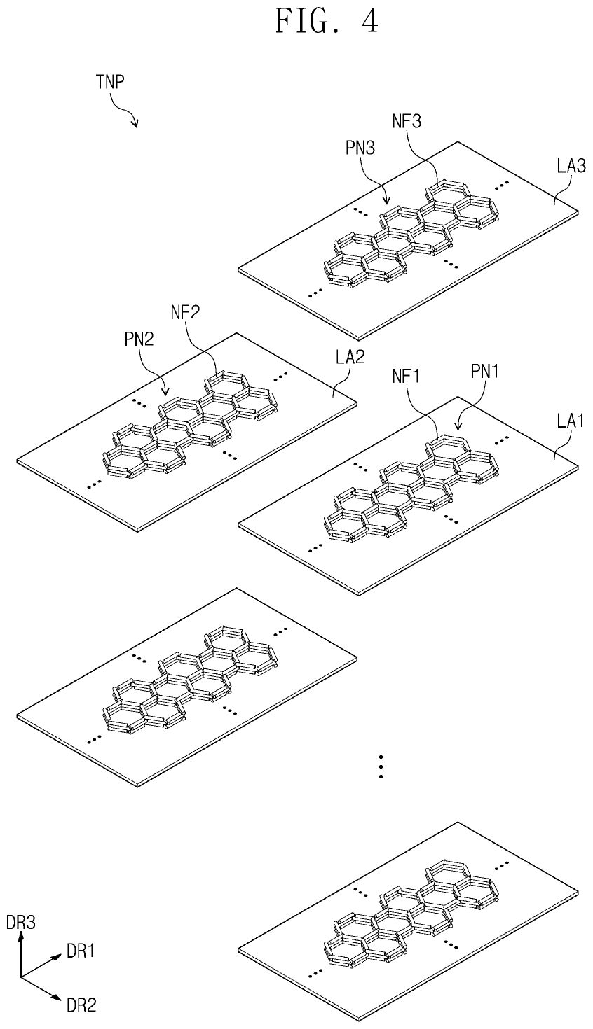

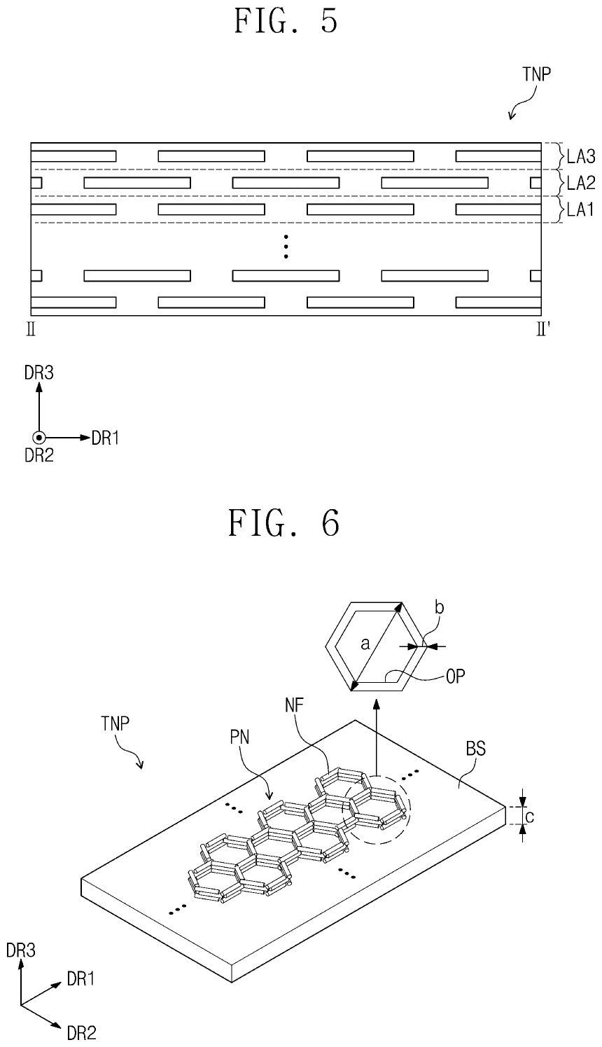

FIG. 3 is a perspective view illustrating the nano-cellulose sheet TNP according to an exemplary embodiment of the present inventive concepts. FIG. 4 is an exploded perspective view illustrating the nano-cellulose sheet TNP according to an exemplary embodiment of the present inventive concepts. FIG. 5 is a cross-sectional view taken along line II-II′ of FIG. 3.

According to an exemplary embodiment of the present inventive concepts, the nano-cellulose sheet TNP includes a base layer BS and a pattern PN. The pattern PN may be obtained by arranging at least one nano-cellulose fiber NF in a hexagonal shape. In an exemplary embodiment, the nano-cellulose fiber NF may be cellulose having a diameter in a range of about 1 nm to about 100 nm. In an exemplary embodiment, the pattern PN may be applied by a spray coating method.

The base layer BS may include a resin. For example, the base layer BS may include an acrylic-based resin. However, exemplary embodiments of the present inventive concepts are not limited thereto.

The pattern PN may be obtained such that a plurality of nano-cellulose fibers NF each having a hexagonal shape extend in the first direction DR1 and the second direction DR2 crossing the first direction DR1 and may have a height in the third direction DR3. For example, as shown in the exemplary embodiment of FIGS. 3-4, the pattern PN may include a plurality of hexagonal shapes that are connected to each other to form a honeycomb shape.

In an exemplary embodiment, the nano-cellulose sheet TNP may include a plurality of nano-cellulose layers each including the pattern PN. For example, as shown in the exemplary embodiment of FIG. 4, the nano-cellulose sheet TNP may include a first layer LA1, a second layer LA2, and a third layer LA3, which are sequentially laminated. In an exemplary embodiment, at least one of the first to third layers LA1, LA2, and LA3 may have a thickness (e.g., length in the third direction DR3) in a range of about 5 μm to about 7 μm. However, exemplary embodiments of the present inventive concepts are not limited thereto and the nano cellulose sheet TNP may have a plurality of layers of varying numbers in other exemplary embodiments. For example, in an exemplary embodiment, the nano-cellulose sheet TNP may have four or more different layers and at least one layer may be misaligned.

As shown in the exemplary embodiment of FIG. 4, the first to third layers LA1, LA2, and LA3 may be sequentially laminated in the third direction DR3,

The first layer LA1 may include a first pattern PN1. In an exemplary embodiment, the first pattern PN1 may be obtained by arranging at least one first nano-cellulose fiber NF1 in a hexagonal shape.

The second layer LA2 may include a second pattern PN2. In an exemplary embodiment, the second pattern PN2 may be obtained by arranging at least one second nano-cellulose fiber NF2 in a hexagonal shape.

The third layer LA3 may include a third pattern PN3. In an exemplary embodiment, the third pattern PN3 may be obtained by arranging a third nano-cellulose fiber NF3 in a hexagonal shape.

In an exemplary embodiment, the first layer LA1 and the second layer LA2 may be arranged in a manner so that the first pattern PN1 and the second pattern PN2 are misaligned when they are laminated together. The second layer LA2 and the third layer LA3 may be arranged in a manner so that the second pattern PN2 and the third pattern PN3 are misaligned when they are laminated together. The first layer LA1 and the third layer LA3 may be arranged so that the first pattern PN1 and the third pattern PN3 are aliened when they are laminated to the second layer LA2.

For example, the first nano-cellulose fiber NF1 may overlap the third nano-cellulose fiber NF3 on a plane defined in the first and second directions DR1, DR2. However, as shown in the exemplary embodiment of FIG. 5, the second nano-cellulose fiber NF2 may include a portion that does not overlap each of the first nano-cellulose fiber NF1 and the third nano-cellulose fiber NF3 on the plane defined in the first and second directions DR1, DR2.

As illustrated in the exemplary embodiment of FIG. 5, the nano-cellulose sheet TNP may include the first to third layers LA1, LA2, and LA3, which are alternately arranged. In an exemplary embodiment, the first to third layer LA1, LA2 and LA3 may be provided in plurality such that the nano-cellulose sheet TNP may include a range of about 70 to about 80 nano-cellulose layers which include the first to third layers LA1, LA2, and LA3.

Referring to the exemplary embodiment of FIGS. 4-5, a plane of the nano-cellulose sheet TNP may be defined in the first direction DR1 and the second direction DR2. A cross-section of the nano-cellulose sheet TNP may be defined as a surface obtained by cutting the nano-cellulose sheet TNP in a direction (e.g., the third direction DR3) crossing the surface defined by the first direction DR1 and the second direction DR2.

In an exemplary embodiment, as the hexagonal shaped pattern PN is arranged on the plane defined in the first and second directions DR1, DR2, the nano-cellulose sheet TNP may have a low modulus on a plane and be flexible to prevent damages such as a crack when the nano-cellulose sheet TNP is folded. Also, since the nano-cellulose sheet TNP has a structure in which the first to third layers LA1, LA2, and LA3 are laminated, the nano-cellulose sheet TNP may have a high modulus on a cross-section and have an increased robustness and durability when the window WM is applied. The nano-cellulose sheet TNP according to an exemplary embodiment of the present inventive concepts may have an anisotropic structure having a low surface modulus and a high cross-sectional modulus to increase the flexibility and durability of the window WM.

FIG. 6 is an enlarged view exemplarily illustrating the pattern PN of the nano-cellulose sheet TNP according to an exemplary embodiment of the present inventive concepts. The pattern PN may be obtained by connecting the plurality of nano-cellulose fibers NF each having a hexagonal shape.

An opening OP having a hexagonal shape may be defined in the pattern PN. For example, the pattern PN may surround the opening OP (e.g., in a plane defined in the first and second directions DR1, DR2). Since the opening OP is defined in the pattern PN, the nano-cellulose sheet TNP may have an improved light transmitting property. For example, in an exemplary embodiment, the nano-cellulose sheet TNP may transmit about 96% or more of the light generated from the display panel DP.

In an exemplary embodiment, the hexagonal-shaped opening contained in the pattern PN may have a diameter in a range of about 10 μm to about 50 μm. Thus, the hexagonal shape of the pattern PN may be in a range of about 10 μm to about 50 μm. In this specification, a diameter of a hexagon may be a linear distance between vertexes facing each other.

While the exemplary embodiments of FIGS. 3, 4 and 6 show the nano-cellulose sheet TNP as having a plurality of hexagonal patterns connected to each other to form a honeycomb shape, exemplary embodiments of the present inventive concepts are not limited thereto. For example, in another exemplary embodiment, the pattern PN of the nano-cellulose sheet TNP formed by the plurality of layers may be configured in a variety of different shapes, such as polygonal, circular or irregular shapes, which font a plurality of openings to provide an increased light transmittance. Additionally, the shape of the pattern of at least one layer of the nano-cellulose sheet TNP may be different from the shapes of another layer of the nano-cellulose sheet TNP.

As shown in the exemplary embodiment of FIG. 6, the at least one nano-cellulose fiber NF which forms the pattern PN surrounding the opening OP may have a diameter b equal to or less than about 1 μm. For example, the nano-cellulose fiber NF may have the diameter b in a range from about 1 nm to about 100 nm.

The nano-cellulose sheet TNP may have a thickness c (e.g., length in the third direction DR3) in a range of about 0.35 mm to about 0.6 mm. For example, in an exemplary embodiment, the nano-cellulose sheet TNP may have a thickness c of about 0.5 mm. Since the nano-cellulose sheet TNP has a small thickness of about 0.5 mm, the display device DD may be relatively thin and may have an improved light transmitting property.

The window WM according to an exemplary embodiment of the present inventive concepts may have an increased light transmitting property and an increased flexibility by including the nano-cellulose sheet. TNP including the pattern PN obtained by arranging the nano-cellulose fiber NF in a hexagonal shape. Also, the nano-cellulose sheet TNP may have increased durability by laminating a plurality of nano-cellulose layers. In an exemplary embodiment, the display device DD may have an increased quality and reliability by including the window WM including the nano-cellulose sheet TNP as a base.

The window according to an exemplary embodiment of the present inventive concepts tray have a small thickness and an increased light transmitting property and flexibility.

The display device according to an exemplary embodiment of the present inventive concepts may include the window having an increased reliability.

Although exemplary embodiments of the present inventive concepts have been described, it is understood that the present inventive concepts should not be limited to these exemplary embodiments but various changes and modifications can be made by one ordinary skilled in the art within the spirit and scope of the present inventive concepts.

What is claimed is:

1. A display device comprising:
a display panel including a light emitting element; and
a nano-cellulose sheet disposed on the display panel, the nano-cellulose sheet is configured to transmit light generated from the light emitting element,
wherein the nano-cellulose sheet comprises a plurality of layers that are sequentially laminated, each of the plurality of layers including a pattern comprising a nano-cellulose fiber arranged in a hexagonal shape.

2. The display device of claim 1, wherein:
the pattern extends in a first direction and a second direction crossing the first direction; and
the plurality of layers are laminated in a third direction crossing each of the first direction and the second direction.

3. The display device of claim 2, wherein:
the nano-cellulose sheet has a surface modulus that is a modulus of a surface defined in the first direction and the second direction; and
the nano-cellulose sheet has a cross-sectional modulus that is a modulus of a surface crossing the surface defined in the first direction and the second direction,
wherein the surface modulus is less than the cross-sectional modulus.

4. The display device, of claim 1, wherein:
the plurality of layers includes a first layer having a first pattern, a second layer having a second pattern and a third layer having a third pattern,
wherein the first to third patterns have a same shape, and
the first to third layers are laminated so that the first pattern and the third pattern are aligned on a plane, and the second pattern is misaligned with each of the first pattern and the third pattern on the plane.

5. The display device of claim 4, wherein:
the first pattern is formed by at least one first nano-cellulose fiber, the second pattern is formed by at least one second nano-cellulose fiber and the third pattern is formed by at least one third nano-cellulose fiber,
wherein the at least one first nano-cellulose fiber and the at least one third nano-cellulose fiber overlap each other on a plane, and
portions of the at least one second nano-cellulose fiber do not overlap the at least one first nano-cellulose fiber and the at least one third nano-cellulose fiber on the plane.

6. The display device of claim 1, wherein the nano-cellulose sheet has a thickness in a range of about 0.35 mm to about 0.6 mm.

7. The display device of claim 1, wherein the hexagonal shape of the pattern has a diameter in a range of about 10 μm to about 50 μm.

8. The display device of claim 1, wherein a hexagonal opening is defined in the pattern.

9. The display device of claim 8, wherein the pattern is formed by a spray coating method.

10. The display device of claim 1, wherein an ink layer having a predetermined color is disposed on a bottom surface of the nano-cellulose sheet.

11. The display device of claim 1, wherein at least one of the first to third layers has a thickness in a range of about 5 μm to about 7 μm.

12. A window comprising a nano-cellulose sheet haying a light transmitting property, wherein:
the nano-cellulose sheet includes a base layer and a pattern, the nano-cellulose sheet comprises a plurality of layers that are sequentially laminated; and
the pattern comprises nano-cellulose fibers arranged in a hexagonal shape.

13. The window of claim 12, wherein:
the pattern extends in a first direction and a second direction crossing the first direction; and
the plurality of layers are laminated in a third direction crossing each of the first direction and the second direction.

14. The window of claim 13, wherein:
the nano-cellulose sheet has a surface modulus that is a modulus of a surface defined in the first direction and the second direction; and
the nano-cellulose sheet has a cross-sectional modulus that is a modulus of a surface crossing the surface defined in the first direction and the second direction,
wherein the surface modulus is less than the cross-sectional modulus.

15. The window of claim 12, wherein:
the plurality of layers includes a first layer having a first pattern, a second layer having a second pattern and a third layer having a third pattern;
the first pattern is formed by at least one first nano-cellulose fiber, the second pattern is formed by at least one second nano-cellulose fiber and the third pattern is formed by at least one third nano-cellulose fiber,
wherein the at least one first nano-cellulose fiber and the at least one third nano-cellulose fiber overlap each other on a plane, and
portions of the at least one second nano-cellulose fiber do not overlap the at least one first nano-cellulose fiber and the at least one third nano-cellulose fiber.

16. The window of claim 12, wherein the nano-cellulose sheet has a thickness in a range of about 0.35 mm to about 0.6 mm.

17. The window of claim 12, wherein the hexagonal shape of the pattern has a diameter in a range of about 10 μm to about 50 μm.

18. The window of claim 12, wherein a hexagonal opening is defined in the pattern.

19. The window of claim 12, wherein the pattern is formed by a spray coating method.

20. The window of claim 12, wherein at least one of the first to third layers has a thickness in a range of about 5 μm to about 7 μm.

21. A display device comprising:
a display panel including a light emitting element; and
a window disposed on the display panel, the window including a nano-cellulose sheet that is configured to transmit light generated from the light emitting element;
wherein the nano-cellulose sheet comprises a plurality of layers that are sequentially laminated, each of the plurality of layers including a pattern comprised of at least one nano-cellulose fiber arranged in a shape that forms a plurality of openings.
